(19) United States
(12) Patent Application Publication
(10) Pub. No.: US 2009/0266410 A1
(43) Pub. Date: Oct. 29, 2009

(54) VACUUM PROCESSING APPARATUS, VACUUM PROCESSING METHOD, ELECTRONIC DEVICE, AND ELECTRONIC DEVICE MANUFACTURING METHOD

(75) Inventor: Katsuya Yoshioka, Kawasaki-shi (JP)

Correspondence Address: BUCHANAN, INGERSOLL & ROONEY PC, POST OFFICE BOX 1404, ALEXANDRIA, VA, 22313-1404, US

(73) Assignee: CANON ANELVA CORPORATION, Kawasaki-shi (JP)

(21) Appl. No.: 12/423,059

(22) Filed: Apr. 14, 2009

(30) Foreign Application Priority Data
Apr. 24, 2008 (JP) 2008-113653

(51) Int. Cl. H01L 31/00; C23C 14/34; F17D 3/00

(52) U.S. Cl. 136/252; 204/298.15; 137/2

(57) ABSTRACT

The present invention provides a vacuum processing apparatus including a process chamber configured to process a target object in a vacuum, a first load-lock chamber configured to store the target object in order to load the target object into the process chamber, a second load-lock chamber configured to store the target object in order to unload the processed target object from the process chamber, and at least two valved pipes configured to connect the first load-lock chamber to the second load-lock chamber.

### BACKGROUND OF THE INVENTION

1. Field of the Invention

The present invention relates to a vacuum processing apparatus including a load-lock chamber or unload-lock chamber to load or unload a target object such as a substrate into or from a process chamber, a vacuum processing method using the vacuum processing apparatus, an electronic device, and an electronic device manufacturing method.

2. Description of the Related Art

In the manufacture of an electronic device including a solar cell and various types of display devices such as a liquid crystal display or plasma display, a plate-like object (to be generically referred to as a substrate hereinafter) serving as the base of the electronic device must undergo processes such as surface processing.

For example, a liquid crystal display requires a process of forming a transparent electrode on the plate surface (a surface which is not an end face) of a glass substrate.

A vacuum processing apparatus used for such a process includes a chamber the interior of which can be evacuated to a vacuum or into which a predetermined gas can be introduced, so that the apparatus processes a substrate in a predetermined atmosphere. The vacuum processing apparatus must perform different processes continuously, and the pressure in the apparatus must be gradually reduced from the atmospheric pressure. For this purpose, the vacuum processing apparatus includes a plurality of chambers (see Japanese Patent Laid-Open No. 2002-158273).

Such conventional vacuum processing apparatuses are roughly divided into two groups in accordance with the chamber layout. One group is called an inline type and the other is called a cluster tool type.

FIG. 3 shows the schematic arrangement of an inline type vacuum processing apparatus as an example of a typical vacuum processing apparatus.

In the inline type vacuum processing apparatus, a plurality of chambers are arranged on a straight line, and a transport system which transports a substrate 9 is arranged to extend through the plurality of chambers. A gate valve 10 is arranged between the adjacent chambers.

The substrate 9 as it is held by a tray 91 is sequentially transported to the respective chambers by the transport system, and undergoes processes.

Of the plurality of chambers, one disposed at one end is a load-lock chamber 11 which is opened to the atmosphere when loading the substrate 9 into it, and one disposed at the other end is an unload-lock chamber 12 which is opened to the atmosphere when unloading the substrate 9 from it.

The plurality of chambers include, in addition to the load-lock chamber 11 and unload-lock chamber 12, a processing chamber (to be referred to as a process chamber hereinafter) 2.

An intermediate chamber 3 as a buffer chamber is arranged between the load-lock chamber 11 and the process chamber 2 closest to it, and between the unload-lock chamber 12 and the process chamber 2 closest to it.

As shown in FIG. 3, the transport system which transports the substrate 9 to the respective chambers is formed of, for example, a tray 91 for holding the substrate 9 and transport wheels 41 for transporting the tray 91. Each transport wheel 41 is formed of a pair of small disk-like members disposed at the two ends of a rotating shaft which is perpendicular to the transport direction and extends in the horizontal direction. The transport wheels 41 are arranged at predetermined intervals in the transport direction. This transport system sequentially transports the substrate 9 held by the tray 91 (in a horizontal state) to each of the plurality of chambers so the substrate 9 is processed.

FIG. 4 shows the schematic arrangement of a cluster tool type vacuum processing apparatus as another example of the typical vacuum processing apparatus. In the cluster tool type vacuum processing apparatus, a load-lock chamber 11 and a plurality of process chambers 2 are arranged around a direction switching chamber 8 incorporating a direction switching mechanism 80.

In FIG. 4, three direction switching chambers 8 are connected to each other, and each direction switching chamber 8 is connected to a plurality of process chambers 2 around it. Of the three direction switching chambers 8, one is connected to an intermediate chamber 7 as a spare chamber. The intermediate chamber 7 is connected to two load-lock chambers 11.

Furthermore, a gate valve 10 is arranged between each direction switching chamber 8 and the corresponding process chamber 2 connected to it, between the intermediate chamber 7 and the direction switching chamber 8 connected to it, and between the intermediate chamber 7 and each load-lock chamber 11.

A transport robot (not shown) is arranged in the intermediate chamber 7. The transport robot takes out a substrate from one load-lock chamber 11 and transfers it to a direction switching mechanism 80 of the direction switching chamber 8. The direction switching mechanism 80 sequentially transports the substrate to the respective process chambers 2 or the adjacent direction switching chamber 8. When the substrate is processed, the transport robot in the intermediate chamber 7 receives the processed substrate from the direction switching mechanism 80 of the adjacent direction switching chamber 8 and returns it into the other load-lock chamber 11.

The transport robot is an articulated robot, and transports the substrate by holding it at the distal end of an arm. More specifically, the transport robot transports the substrate to a predetermined position by the telescopic motion, rotating motion, and vertical motion of the arm. The substrate is transported as it is held in the horizontal posture by the arm. In the process chamber 2 as well, the substrate 9 is processed while maintaining the horizontal posture.

In recent years, the size of the substrate to be processed by the vacuum processing apparatus described above increases.

For example, among electronic devices, a display device such as a liquid crystal display or plasma display is introduced not only in a computer display but also in a wall-hanging television, and is becoming very popular. A wall-hanging television has a larger display area than a computer display, and accordingly its substrate size increases. This applies to the production of solar cells as well. The general trend is toward improvement of the productivity and reduction of the manufacturing cost by, for example, manufacturing two or more products from one substrate. Accordingly, the substrate size increases.

As the substrate has a larger size in this manner, the vacuum processing apparatus described above has, or will have in the future, the following problem.

The load-lock chamber must be evacuated by an exhaust system from the atmospheric pressure to a predetermined vacuum degree. Along with an increase in substrate size, when the size of the load-lock chamber increases, it takes time for the load-lock chamber to be evacuated to the predetermined vacuum degree.

More specifically, the evacuation time is generally determined by the exhaust velocity of the exhaust system and the displacement. The size increase (that is, an increase in capacity) of the load-lock chamber leads to a long evacuation time. In addition, the tact time since loading, via the process, until unloading of the substrate is largely influenced by the evacuation time taken until the atmosphere in the load-lock chamber as the substrate loading port reaches such a pressure that the load-lock chamber can communicate with the process chamber, that is, the evacuation time of the load-lock chamber.

Therefore, when the substrate size increases, the evacuation time of the load-lock chamber must be shortened.

### SUMMARY OF THE INVENTION

The present invention provides a technique that can shorten the tact time that takes since loading, via the process, until unloading of the substrate.

According to the first aspect of the present invention, there is provided a vacuum processing apparatus including a process chamber configured to process a target object in a vacuum, a first load-lock chamber configured to store the target object in order to load the target object into the process chamber, a second load-lock chamber configured to store the target object in order to unload the processed target object from the process chamber, and at least two valved pipes configured to connect the first load-lock chamber to the second load-lock chamber.

According to the second aspect of the present invention, there is provided a vacuum processing method using a vacuum processing apparatus including a process chamber configured to process a target object in a vacuum, a first load-lock chamber configured to store the target object in order to load the target object into the process chamber, a second load-lock chamber configured to store the target object in order to unload the processed target object from the process chamber, and at least two valved pipes configured to connect the first load-lock chamber to the second load-lock chamber, the method including a comparison step of comparing a vacuum degree of the first load-lock chamber with that of the second load-lock chamber, and a communication step of causing the first load-lock chamber to communicate with the second load-lock chamber by manipulating valves of the at least two valved pipes in accordance with a comparison result in the comparison step.

According to the third aspect of the present invention, there is provided an electronic device including a target object processed by the above vacuum processing apparatus.

According to the fourth aspect of the present invention, there is provided an electronic device manufacturing method which uses the above vacuum processing method.

Further features of the present invention will become apparent from the following description of exemplary embodiments with reference to the attached drawings.

### BRIEF DESCRIPTION OF THE DRAWINGS

FIG. 1 is a schematic plan view showing the overall arrangement of a vacuum processing apparatus as one aspect of the present invention.

FIG. 2 is a schematic view of two load-lock chambers connected by valved pipes according to the present invention, which is seen from the side of the apparatus.

FIG. 3 is a view showing the schematic arrangement of an inline type vacuum processing apparatus as an example of a typical vacuum processing apparatus.

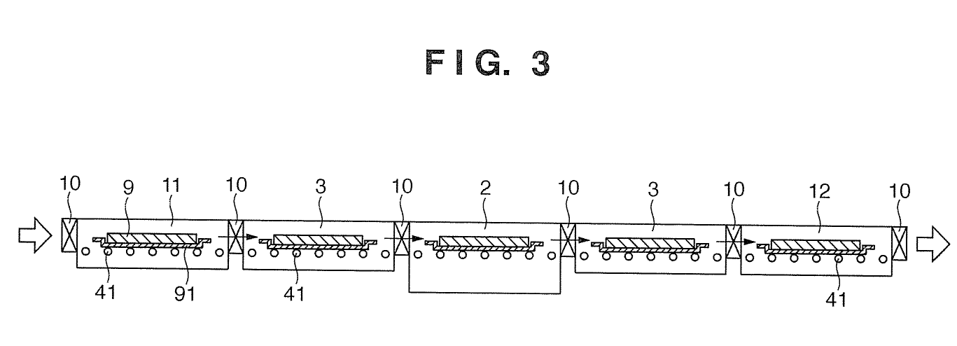

FIG. 4 is a view showing the schematic arrangement of a cluster tool type vacuum processing apparatus as another example of the typical vacuum processing apparatus.

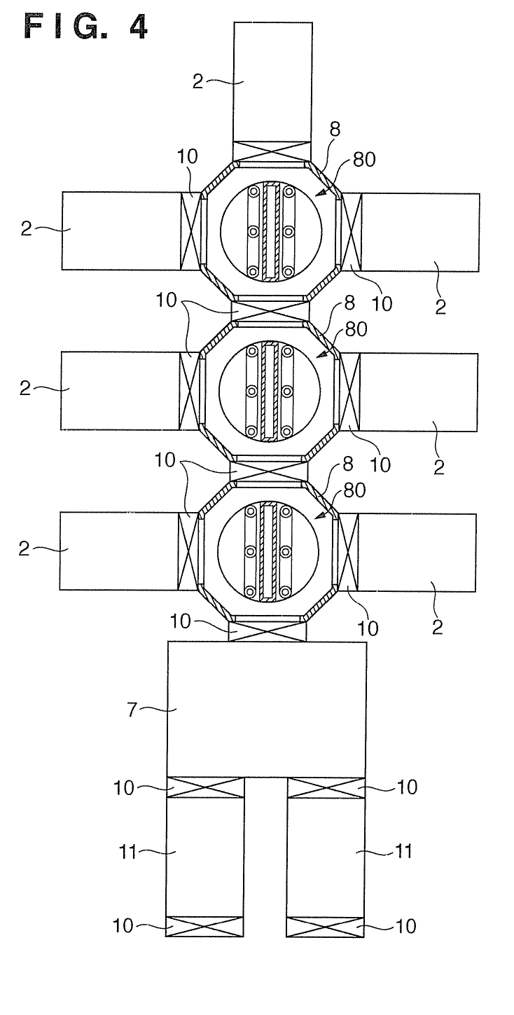

### DESCRIPTION OF THE EMBODIMENT

The preferred embodiment of the present invention will be described hereinafter with reference to the accompanying drawings. In the drawings, the same members are denoted by the same reference numerals, and a repetitive description will be omitted.

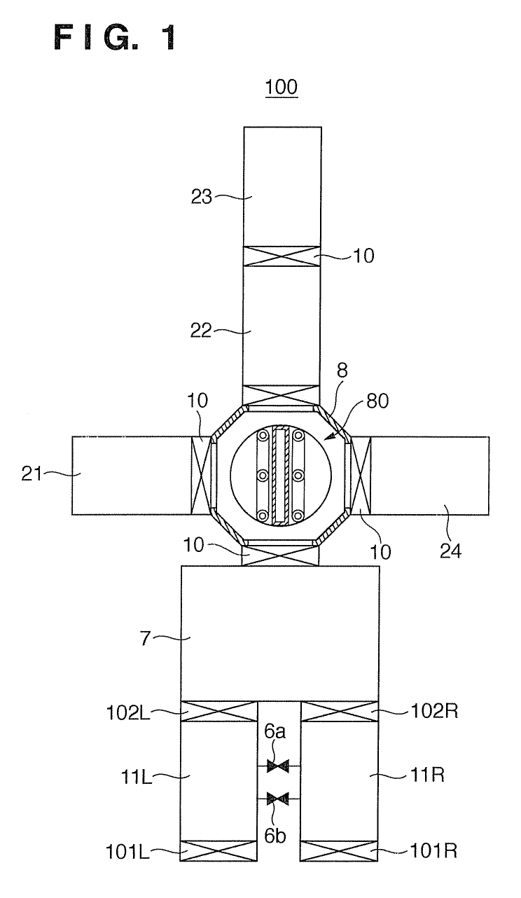

FIG. 1 is a schematic plan view showing the overall arrangement of a vacuum processing apparatus 100 according to one aspect of the present invention.

The vacuum processing apparatus 100 has a structure in which a plurality of vacuum chambers, including process chambers 21, 22, 23, and 24, which perform a predetermined process for a substrate as a target object in a vacuum are hermetically connected to each other. The vacuum processing apparatus 100 also has a transport system (not shown) which sequentially transports the substrate to the respective vacuum chambers.

Of the plurality of vacuum chambers, for example, one is a direction switching chamber 8 provided with a direction switching mechanism 80 which switches the substrate transport direction. The direction switching chamber 8 is connected to the four process chambers 21, 22, 23, and 24 around it.

The direction switching chamber 8 is also connected to an intermediate chamber 7 serving as a buffer chamber, and the intermediate chamber 7 is connected to a first load-lock chamber 11L and second load-lock chamber 11R.

According to this embodiment, the first load-lock chamber 11L serves as a substrate loading port, and stores the substrate to load it from outside the first load-lock chamber 11L into a predetermined process chamber.

The second load-lock chamber 11R serves as a substrate unloading port, and stores the processed substrate to unload it from the process chamber to outside the second load-lock chamber 11R.

Each of the first load-lock chamber 11L, second load-lock chamber 11R, process chambers 21, 22, 23, and 24, intermediate chamber 7, and direction switching chamber 8 is provided with an exhaust system (not shown) which evacuates the interior of the corresponding chamber.

The exhaust system communicates with an exhaust pump such as a turbo molecular pump or cryopump, and includes a pipe and valve to evacuate the interior of the chamber to a predetermined pressure region. The exhaust pump is connected to an exhaust port formed in the bottom surface of the corresponding chamber.

A gate valve 10 is arranged between the direction switching chamber 8 and each of the respective process chambers 21, 22, and 24 connected to it, between the process chambers 22 and 23, and between the intermediate chamber 7 and the direction switching chamber 8 connected to it.

Similarly, gate valves 102L and 102R are arranged between the intermediate chamber 7 and first load-lock chamber 11L and between the intermediate chamber 7 and second load-lock chamber 11R, respectively. Gate valves 101L and 101R are disposed at the substrate loading port of the first load-lock chamber 11L and the substrate unloading port of the second load-lock chamber 11R, respectively.

As shown in FIG. 1, the first load-lock chamber 11L and second load-lock chamber 11R are connected to each other through at least two valved pipes 6a and 6b. The valved pipes 6a and 6b open/close the valves in accordance with the difference in detection pressure between pressure sensors (not shown) set in, for example, the first load-lock chamber 11L and second load-lock chamber 11R, respectively.

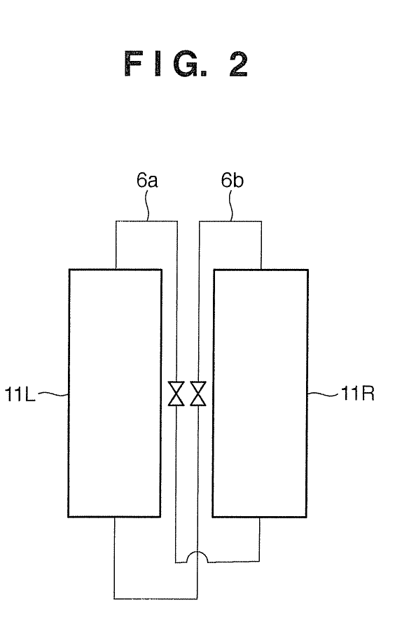

Connection of the valved pipes 6a and 6b will be described with reference to FIG. 2. FIG. 2 is a view of the first load-lock chamber 11L and second load-lock chamber 11R seen from the side of the apparatus.

As shown in FIG. 2, the valved pipe 6a is provided to connect the ceiling surface of the first load-lock chamber 11L serving as the substrate loading port to the bottom surface of the second load-lock chamber 11R serving as the substrate unloading port. The valved pipe 6b is provided to connect the bottom surface of the first load-lock chamber 11L to the ceiling surface of the second load-lock chamber 11R.

According to this embodiment, one of the connection ports at the two ends of each of the valved pipes 6a and 6b connected to the first load-lock chamber 11L and second load-lock chamber 11R is disposed to face the bottom surface where the exhaust system of the corresponding chamber is disposed. Thus, when opening the chamber to the atmosphere for loading the substrate or evacuating the chamber for unloading the substrate, dust scattering in the corresponding load-lock chamber can be suppressed.

The vacuum processing apparatus 100 transports and processes the target substrate by, for example, holding it vertically or at an angle close to the vertical direction. More specifically, the transport system has a substrate holding tool and horizontal moving mechanism. The substrate holding tool holds the substrate upright such that its plate surface is at an angle of 45° to 90° (both inclusive) with respect to the horizontal direction. The horizontal moving mechanism transports the substrate by moving the substrate holding tool in the horizontal direction.

A load station (not shown) is arranged outside the first load-lock chamber 11L and second load-lock chamber 11R. The load station serves to mount an unprocessed substrate on the substrate holding tool and recover the processed substrate from the substrate holding tool.

The substrate loading/unloading operation in the substrate processing using the vacuum processing apparatus 100 according to this embodiment will be described hereinafter together with the operation of the valved pipes 6a and 6b.

First, the gate valve 101L is opened, and a plurality of substrates is loaded into the first load-lock chamber 11L which is open to the atmosphere. The gate valve 101L is closed, and the exhaust pump or the like evacuates the interior of the first load-lock chamber 11L to a predetermined vacuum degree.

At this time, although the gate valve 101R provided at the substrate unloading port of the second load-lock chamber 11R is closed, the interior of the second load-lock chamber 11R is maintained at atmospheric pressure. Also, both of the valved pipes 6a and 6b are closed (this will be referred to as a closed state hereinafter; when they are open, their state will be referred to as an open state hereinafter).

In the first load-lock chamber 11L that has reached the predetermined vacuum degree, the gate valve 102L between the first load-lock chamber 11L and intermediate chamber 7 is opened. All the substrates transported to the first load-lock chamber 11L are transported to the intermediate chamber 7. Then, the gate valve 102L is closed again.

At this time, the closed valve of the valved pipe 6a is opened so that the first load-lock chamber 11L in the vacuum state communicates with the second load-lock chamber 11R maintained at a vacuum degree close to the atmospheric pressure. This adjusts the pressures in the two chambers 11L and 11R to be equal to each other.

When the pressures in the first load-lock chamber 11L and second load-lock chamber 11R become equal to each other by the manipulation described above, the valve of the valved pipe 6a is closed.

After that, a vent valve (not shown) provided to the first load-lock chamber 11L is opened, so that the first load-lock chamber 11L is kept open to outside (vented) until the vacuum degree in it reaches the atmospheric pressure. This completes the preparation for loading the next substrate into the first load-lock chamber 11L.

According to the present invention, before opening the first load-lock chamber 11L to the atmosphere, the valve of the valved pipe 6a is manipulated to restore the pressure in the first load-lock chamber 11L which has been at the vacuum state to the atmospheric pressure. Thus, the open time of the first load-lock chamber 11L into which the next substrate is to be transported can be shortened. Although one valved pipe 6a is employed in this embodiment, two or more valved pipes 6a may be provided where necessary.

The gate valve 101L mainly serves to open and close the substrate loading opening, and does not serve sufficiently to adjust the pressure appropriately. Hence, if the gate valve 101L of the first load-lock chamber 11L in the vacuum state is opened without manipulating the vent valve, air outside the apparatus undesirably flows into the first load-lock chamber 11L at once through the substrate loading port. To prevent this, the vent valve must be manipulated, as described above, and a unit that can shorten the vent time is manipulation of the valve of the valved pipe 6a.

When the valve of the valved pipe 6a is opened as described above, gas in the second load-lock chamber 11R which is at a vacuum degree close to atmospheric pressure may quickly flow into the first load-lock chamber 11L in the vacuum state and scatter dust in it. To prevent this, as shown in FIG. 2, the connection port of the valved pipe 6a connected to the first load-lock chamber 11L is directed to the bottom surface of the first load-lock chamber 11L where the exhaust system is arranged. Then, the gas flows from the ceiling side to the bottom surface side of the first load-lock chamber 11L, in the same manner as in exhausting the gas. As a result, dust scattering can be suppressed.

The substrate unloading side will be described. The second load-lock chamber 11R serving as the substrate unloading port is evacuated until its interior reaches a predetermined vacuum degree, so that it can recover the plurality of substrates that have undergone processes in the process chambers 21, 22, 23, and 24. At this time, the gate valve 101R of the second load-lock chamber 11R is closed.

When the interior of the second load-lock chamber 11R reaches the predetermined vacuum degree, the gate valve 102R between the second load-lock chamber 11R and intermediate chamber 7 is opened. All the processed substrates are unloaded to the second load-lock chamber 11R through the intermediate chamber 7. Then, the gate valve 102R is closed again.

After that, the vacuum degree in the first load-lock chamber 11L is compared with that in the second load-lock chamber 11R. As a result of the comparison, if the vacuum degree in the second load-lock chamber 11R is lower than that in the first load-lock chamber 11L, the closed valved pipe 6b is opened, so the second load-lock chamber 11R communicates with the first load-lock chamber 11L. This adjusts the pressures in the two second load-lock chambers 11R and 11L to be equal to each other. Although one valved pipe 6b is provided in this embodiment, two or more valved pipe 6a may be provided where necessary.

At this time, gas in the first load-lock chamber 11L may flow into the second load-lock chamber 11R and scatter dust in it. To prevent this, as shown in FIG. 2, the connection port of the valved pipe 6b which is connected to the second load-lock chamber 11R is directed to the bottom surface of the second load-lock chamber 11R where the exhaust system is arranged. Then, the gas flows from the ceiling side to the bottom surface side of the second load-lock chamber 11R, in the same manner as in exhausting the gas. As a result, dust scattering can be suppressed.

By manipulating the valved pipe 6b in this manner, the exhaust velocity of the first load-lock chamber 11L the interior of which has been at a higher pressure than that in the second load-lock chamber 11R can be accelerated.

More specifically, when the next substrate is loaded into the first load-lock chamber 11L which is open to the atmosphere, the gate valve 101L is closed, and the first load-lock chamber 11L is to be evacuated to the predetermined vacuum degree, the exhaust time can be shortened by utilizing the vacuum degree of the second load-lock chamber 11R.

Selection of the valved pipe 6a or 6b to be manipulated, and selection of the closed/open state of the valve of the selected valved pipe are performed appropriately in accordance with the comparison result of the detected vacuum degrees of the first and second load-lock chambers 11L and 11R, and the state of the substrate processing procedure.

According to this embodiment, the first load-lock chamber 11L is described as a chamber to load the target object into the process chamber, and the second load-lock chamber 11R is described as a chamber to unload the target object processed in the process chamber to the atmosphere. However, the present invention can also be applied to a vacuum processing apparatus which includes a plurality of load-lock chambers, including the first load-lock chamber 11L and second load-lock chamber 11R, as chambers that can be used for both loading and unloading the target object.

As has been described above, this embodiment can achieve a remarkable effect of shortening the time necessary for opening the substrate loading side load-lock chamber to the atmosphere and evacuating the substrate unloading side load-lock chamber, thus shortening the tact time in the substrate processing.

Also, according to this embodiment, dust scattering in the substrate loading side load-lock chamber or substrate unloading side load-lock chamber can be prevented, so that a high processing quality for the electronic device can be maintained.

### Example 1

Using the vacuum processing apparatus 100 in which a Mo target was arranged in a process chamber, a substrate having a size of 730 mm×920 mm was processed. A solar cell as an electronic device was thus manufactured.

The solar cell including a compound semiconductor is manufactured by depositing respective thin films, that is, a Mo electrode layer serving as a lower surface electrode (positive electrode) on a substrate, a light-absorbing layer on the Mo electrode layer, and a transparent electrode layer made of ZnO Al or the like and serving as a negative electrode on the light-absorbing layer through a buffer layer made of ZnS, CdS, or the like.

This film formation was performed in the process chamber by sputtering using a magnetron type cathode.

As a Mo sputtering gas, Ar was employed. The substrate described above was set in a sputtering chamber serving as the process chamber. After the interior of the sputtering chamber was evacuated, Ar was supplied into the chamber at a flow rate of 90 sccm while evacuating the chamber, so that the pressure was maintained at 0.4 Pa.

Sputtering power of 60 kW was supplied from a DC variable power supply to the magnetron type cathode, thus forming a Mo film having an average thickness of 150 nm.

Similarly, a solar cell was manufactured by forming respective thin films, that is, a light-absorbing layer on a Mo electrode layer, a buffer layer on the light-absorbing layer, and a transparent electrode layer serving as a negative electrode on the buffer layer. After sputtering the substrate was unloaded from the load-lock chamber, well without scattering dust.

The substrate to be processed by the vacuum processing apparatus of this embodiment includes, in addition to the substrate described above for manufacturing the solar cell, a semiconductor wafer for manufacturing a semiconductor device, a substrate for a display device such as a liquid crystal display or plasma display, a substrate for an information storage medium such as a hard disk, and a substrate for a printed wiring board.

The present invention is not limited to such substrate processing, but can be applied to any target object as far as it requires processing in a vacuum atmosphere.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-113653 filed on Apr. 24, 2008, which is hereby incorporated by reference herein in its entirety.

What is claimed is:

1. A vacuum processing apparatus comprising:
a process chamber configured to process a target object in a vacuum;
a first load-lock chamber configured to store the target object in order to load the target object into said process chamber;
a second load-lock chamber configured to store the target object in order to unload the processed target object from said process chamber; and
at least two valved pipes configured to connect said first load-lock chamber to said second load-lock chamber.

2. The apparatus according to claim 1, wherein
a connection port of one of said at least two valved pipes which is connected to said first load-lock chamber is directed to a bottom surface of said first load-lock chamber, and
a connection port of one of said at least two valved pipes which is connected to said second load-lock chamber is directed to a bottom surface of said second load-lock chamber.

3. The apparatus according to claim 1, further comprising an exhaust system communicating with an exhaust pump which evacuates an interior of said first load-lock chamber and an interior of said second load-lock chamber,
said exhaust system being disposed on the bottom surface of said first load-lock chamber and the bottom surface of said second load-lock chamber.

4. The apparatus according to claim 1, further comprising a plurality of load-lock chambers used for loading and unloading the target object and including said first load-lock chamber and said second load-lock chamber.

5. A vacuum processing method using a vacuum processing apparatus comprising a process chamber configured to process a target object in a vacuum, a first load-lock chamber configured to store the target object in order to load the target object into the process chamber, a second load-lock chamber configured to store the target object in order to unload the processed target object from the process chamber, and at least two valved pipes configured to connect the first load-lock chamber to the second load-lock chamber, the method comprising:
a comparison step of comparing a vacuum degree of the first load-lock chamber with that of the second load-lock chamber; and
a communication step of causing the first load-lock chamber to communicate with the second load-lock chamber by manipulating valves of the at least two valved pipes in accordance with a comparison result in the comparison step.

6. The method according to claim 5, wherein when opening the first load-lock chamber which is in a vacuum state to the atmosphere, the valves of the valved pipes are manipulated so that the first load-lock chamber which is in the vacuum state communicates with the second load-lock chamber which is in a state closer to the atmospheric pressure than the first load-lock chamber.

7. The method according to claim 5, wherein when reducing, by evacuating, a pressure in the first load-lock chamber which is open to the atmosphere, the valves of the valved pipes are manipulated so that the first load-lock chamber which open to the atmosphere communicates with the second load-lock chamber which is in the vacuum state.

8. An electronic device including a target object processed by a vacuum processing apparatus according to claim 1.

9. An electronic device manufacturing method which uses a vacuum processing method according to claim 5.
